(19) United States
(12) Patent Application Publication
(10) Pub. No.: US 2026/0101649 A1
(43) Pub. Date: Apr. 9, 2026

(54) DISPLAY DEVICE AND METHOD FOR MANUFACTURING THE SAME

(71) Applicant: LG Display Co., Ltd., Seoul (KR)

(72) Inventors: Jaehyung JO, Goyang-si (KR); Chaiwon KIM, Seongnam-si (KR); Youngmin JEONG, Paju-si (KR); Inyeong KONG, Seoul (KR)

(73) Assignee: LG Display Co., Ltd., Seoul (KR)

(21) Appl. No.: 19/267,272

(22) Filed: Jul. 11, 2025

(30) Foreign Application Priority Data
Oct. 4, 2024 (KR) 10-2024-0134733

(51) Int. Cl. H10K 59/131; H10K 59/12

(52) U.S. Cl. CPC H10K 59/131; H10K 59/1201

(57) ABSTRACT

A display device can include a first active line and a second active line arranged in a row direction and extending in a column direction, and a repair area extending across the first active line and the second active line in the row direction. Also, the repair area includes a cutting area vertically overlapping with the first active line and the second active line, and a groove area vertically non-overlapping with the first active line and the second active line, the groove area including at least one groove.

### CROSS-REFERENCE TO RELATED APPLICATION

This application claims priority to Korean Patent Application No. 10-2024-0134733 filed on Oct. 4, 2024 in the Republic of Korea, and all the benefits accruing therefrom under 35 U.S.C. 119, the entirety of which is herein incorporated by reference into the present application.

### BACKGROUND

### Field

The present disclosure relates to a display device, and more particularly, to a display device in which cutting repair is able to be performed, and a method for manufacturing the same.

### Description of Related Art

An organic light-emitting display device is a self-emission display device. Unlike the liquid crystal display device, a separate light source is not required in the organic light-emitting display device (e.g., no backlight needed). Thus, the organic light-emitting display device can be manufactured in a lightweight and thin manner. In addition, the organic light-emitting display device is advantageous in terms of power consumption due to low voltage operation, and has excellent color gamut, fast response speed, large viewing angle, and high contrast ratio (CR), and thus is being studied as a next-generation display.

As the resolution increases, the frequency of occurrence of a defective pixel due to electrical connectivity of components provided in the pixel or a defect of the element itself increases. When a defective pixel is present, a repair scheme of cutting a connection with the defective pixel and connecting to a normal pixel may be performed.

In a high PPI (pixels per inch) pixel, particularly, a double rate driving (DRD) type pixel, the lines of the active layer are concentrated in an opening area, such that a spacing between the lines is set to a minimum distance at which the lines can be patterned. In order to secure the high PPI aperture ratio, a light shield (LS) floating metal is used to improve the structure of a cutting area for repair.

However, in the DRD pixel, an area in which the floating metal is to be inserted is narrow, such that only the spacing between the lines is inevitably small, which inevitably causes a short-circuit between patterns. For this reason, an improvement scheme is required to overcome this problem. Thus, a need exists for a display device having a configuration in which a cutting repair is able to be performed without causing a short-circuit between patterns in a high PPI pixel or a DRD type pixel, and a method for manufacturing the same.

### SUMMARY OF THE DISCLOSURE

A purpose to be achieved according to an embodiment of the present disclosure is to provide a display device in which cutting repair can be performed without causing a short-circuit between patterns in a high-PPI pixel or a DRD type pixel, and a method for manufacturing the same.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure is provided. The display device includes a repair area extending across a first active line and a second active line in a row direction, in which the repair area includes a cutting area vertically overlapping the first active line and the second active line, and a groove area vertically non-overlapping the first active line and the second active line and having a groove defined therein.

According to some embodiments, the cutting area includes a light-shielding layer formed on a substrate, a buffer layer formed on the light-shielding layer, and an active layer formed on the buffer layer. In accordance with some embodiments, in the groove area, the groove is formed by removing the light-shielding layer and the buffer layer on the substrate.

According to some embodiments, the display device further includes a marker area disposed on each of both opposing sides in the row direction of the repair area, in which the marker area includes a light-shielding layer formed on a substrate, a buffer layer formed on the light-shielding layer, and a gate insulating layer formed on the buffer layer.

A method for manufacturing a display device according to an embodiment of the present disclosure is provided. The method for manufacturing the display device includes defining a repair area to extend a first active line and a second active line in a row direction, dividing the repair area into a cutting area and a groove area, and etching a gate insulating layer in the repair area and etching a buffer layer in the groove area.

According to some embodiments, the method further includes defining a marker area on each of both opposing sides in the row direction of the repair area, depositing a gate layer in the repair area and the marker area; and patterning the gate layer. The patterning of the gate layer includes removing the gate layer in the repair area and the marker area, and removing a light-shielding layer in the groove area.

According to an embodiment of the present disclosure, the repair structure included in the display panel includes the repair area extending across the first active line and the second active line in the row direction. The repair area includes the cutting area corresponding to (vertically overlapping) the first active line and the second active line and the groove area not corresponding to (vertically non-overlapping) the first active line and the second active line and having the groove defined therein. The cutting repair can be performed in the high PPI pixel or the DRD pixel without causing a short-circuit between patterns during the cutting repair of a specific pixel.

In addition, the repair structure included in the display panel has a structure in which the groove area of the repair area is formed by removing the light-shielding layer and the buffer layer on the substrate to form the groove. Thus, the cutting repair can be performed without causing a short-circuit between patterns in a pixel having a structure in which a margin is insufficient due to a large number of lines in an opening area at a high resolution.

In addition, the repair structure included in the display panel further includes the marker area on each of both opposing sides of the repair area, so that the repair area can be identified based on the pattern of the marker area and the cutting repair can be accurately performed at a desired position by irradiating a laser onto an extension line passing through the both maker areas in the row direction.

In addition, the groove area of the repair area has a structure in which the light-shielding layer and the gate layer are removed from the groove area compared to a general hole patterning and a gate layer-light-shielding layer contact structure. Since the process of forming the pattern of the groove area is the same as the process of forming the contact hole via which the light-shielding layer-active layer-gate layer contact each other, an additional process does not occur.

Further, when the active line is made of a transparent IGZO, the light-shielding layer disposed thereunder can be visible to the user to recognize the cutting area.

In addition, even when the active line is not a transparent line, the cutting area can be recognized due to the generation of shading due to a step formed at each of both opposing sides of the cutting area.

Furthermore, the active line passing over the light-shielding layer has an incomplete contact area such as folds and pores. Thus, when a laser is applied thereto, a crack is generated therein at which the cutting occurs.

Moreover, the overlay margin in the row direction of the light-shielding layer is unnecessary compared to the active line to be cut. Thus, a desired cutting repair can be performed without a short-circuit between the active lines even in a pixel structure in which the margin is insufficient due to the large number of lines in the opening area in the high PPI pixel.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

The above and other objects, features, and advantages of the present disclosure will become more apparent to those of ordinary skill in the art by describing example embodiments thereof in detail with reference to the attached drawings, which are briefly described below.

FIG. 1 is a block diagram illustrating an organic light-emitting display device according to an embodiment of the present disclosure.

FIG. 2 is a circuit diagram of a pixel included in an organic light-emitting display device according to an embodiment of the present disclosure.

FIG. 3 is a plan view of a pixel included in an organic light-emitting display device according to an embodiment of the present disclosure.

FIG. 4 is a plan view illustrating a repair structure included in an organic light-emitting display device according to an embodiment of the present disclosure.

FIG. 5 is a cross-sectional view taken along a line I-I′ in a repair structure included in an organic light-emitting display device according to an embodiment of the present disclosure.

FIG. 6 is a cross-sectional view taken along a line II-II′ in a repair structure included in an organic light-emitting display device according to an embodiment of the present disclosure.

FIGS. 7a and 7b are cross-sectional views sequentially illustrating a manufacturing process of an organic light-emitting display device according to an embodiment of the present disclosure.

### DETAILED DESCRIPTION OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to,” or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween.

Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former can directly contact the latter or still another layer, film, area, plate, or the like can be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event can occur therebetween unless “directly after,” “directly subsequent” or “directly before” is not indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first,” “second,” “third,” and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship. Also, the term “can” used herein includes all meanings and definitions of the term “may.”

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific situation, a term may be arbitrarily selected by the applicant, and in this situation, the detailed meaning thereof will be described in a corresponding description period. Therefore, the terms used in the description as set forth below should be understood based on not simply the name of the terms, but the meaning of the terms and the contents throughout the detailed descriptions.

In description of flow of a signal, for example, when a signal is delivered from a node A to a node B, this can include a situation where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure can work functionally.

Hereinafter, various embodiments of the present disclosure will be described in detail with reference to the accompanying drawings.

In a plan view of the display device, a column direction and a row direction intersecting each other are used to define an extension direction of a component, for example, a line.

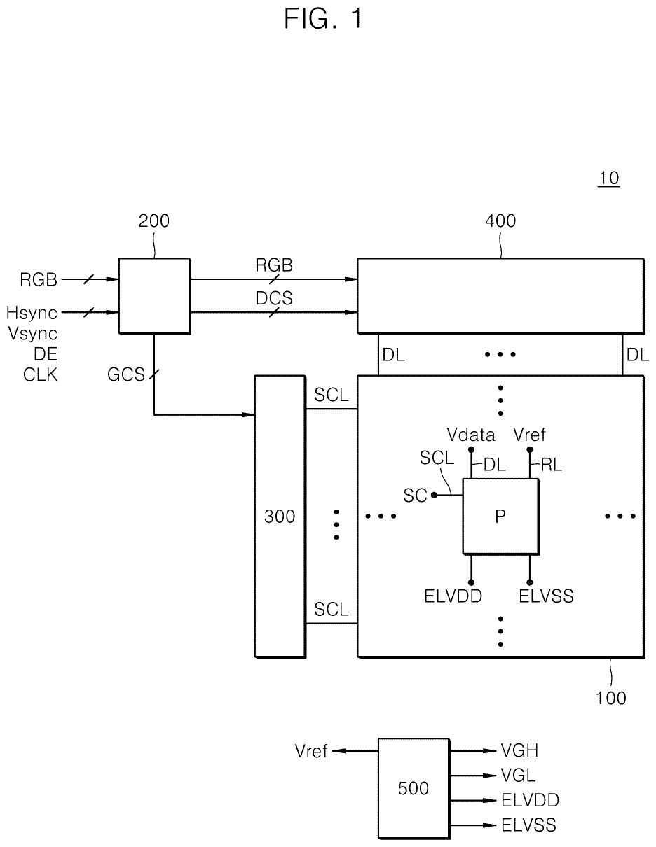

FIG. 1 is a block diagram illustrating an organic light-emitting display device according to an embodiment of the present disclosure.

Referring to FIG. 1, a display device 10 includes a display panel 100 including a plurality of pixels P, a controller 200, a gate driver 300 configured to supply a scan signal SC to the plurality of pixels P, a data driver 400 configured to supply a data voltage Vdata to the plurality of pixels P, and a power supply 500 configured to supply voltages necessary for driving the plurality of pixels P.

In the display panel 100, a plurality of scan lines SCL and a plurality of data lines DL intersect each other, and each of the plurality of pixels P is connected to the scan line SCL and the data line DL. Specifically, one pixel P receives the scan signal SC through the scan line SCL, receives the data voltage Vdata through the data line DL, and receives a reference voltage Vref, a high potential driving voltage ELVDD, and a low potential driving voltage ELVSS from the power supply 500.

The scan line SCL supplies the scan signal SC and the sensing signal to the pixel P, and the data line DL supplies the data voltage Vdata to the pixel P. In addition, according to various embodiments, a sensing line for supplying the sensing signal can be individually connected to the pixel P.

In addition, the plurality of pixels P can receive the high-potential driving voltage ELVDD and the low-potential driving voltage ELVSS via the power lines to and can receive the reference voltage Vref via a reference voltage line RL.

In addition, each of the pixels P includes a light-emitting element and a pixel circuit for controlling driving of the light-emitting element. The pixel circuit includes a plurality of switching elements, a driving element, and a capacitor. In this regard, each of the switching element and the driving element can be embodied as a thin-film transistor. In the pixel circuit, the driving element controls the amount of current supplied to the light-emitting element according to the data voltage to adjust the amount of light emitted from the light-emitting element. In addition, the plurality of switching elements receive the scan signal SC supplied through the plurality of scan lines SCL and the reference voltage Vref supplied through the reference voltage line RL and operate the pixel circuit based on the received scan signal the received reference voltage.

The display panel 100 can be implemented as a non-transmissive display panel or a transmissive display panel. The transmissive display panel can be applied to a transparent display device in which an image is displayed on a screen and a real object in the background is visible to a viewer in front of the display device. The display panel 100 can be manufactured as a flexible display panel. The flexible display panel can be implemented as an OLED panel using a plastic substrate.

The pixels P can include a red pixel, a green pixel, and a blue pixel. Each of the pixels P can further include a white pixel.

Touch sensors TS can be disposed on the display panel 100. The touch input can be sensed using separate touch sensors or can be sensed via the pixels P. The touch sensor can be implemented as an on-cell type touch sensor or an add-on type touch sensor in which the touch sensor is disposed on the screen of the display panel or as an in-cell type touch sensor in which the touch sensor is embedded in the display panel 100.

The controller 200 processes image data RGB input from a host system to be suitable for the size and a resolution of the display panel 100 and supplies the processed image data RGB to the data driver 400. The controller 200 generates a gate control signal GCS and a data control signal DCS using synchronization signals input from an external source, for example, a clock signal CLK, a data enable signal DE, a horizontal synchronization signal Hsync, and a vertical synchronization signal Vsync. The gate control signal GCS and the data control signal DCS are supplied to the gate driver 300 and the data driver 400, respectively, to control the gate driver 300 and the data driver 400.

A voltage level of the gate control signal GCS output from the controller 200 can be converted into a gate-on voltage and a gate-off voltage through a level shifter and can be supplied to the gate driver 300. The level shifter converts the low level voltage of the gate control signal GCS into a gate low voltage VGL, and converts the high level voltage of the gate control signal GCS into a gate high voltage VGH. The gate control signal GCS includes a start pulse and a shift clock.

The gate driver 300 supplies the scan signal SC to the scan line SCL according to the gate control signal GCS. The gate driver 300 can be disposed on one side or each of both opposing sides of the display panel 100 in a gate in panel (GIP) manner.

The gate driver 300 sequentially outputs the scan signal SC to the plurality of scan lines SCL. The gate driver 300 can sequentially supply the scan signal SC to the scan line SCL by shifting the scan signal SC using a shift register. The scan signal SC can include a scan pulse that swings between the gate low voltage VGL and the gate high voltage VGH. In addition, according to various embodiments, the gate driver 300 sequentially outputs the sensing signal to the plurality of sensing lines SL. The sensing signal can include a scan pulse that swings between the gate low voltage VGL and the gate high voltage VGH.

The gate driver 300 outputs the scan pulse SCP in response to the start pulse and the shift clock from the controller 200, and sequentially shifts the scan pulse according to the shift clock.

The data driver 400 converts the image data RGB into a data voltage Vdata according to the data control signal DCS, and supplies the converted data voltage Vdata to the pixel P through the data line DL.

Although FIG. 1 illustrates that the data driver 400 is disposed in a single manner and on one side of the display panel 100, the number and arrangement position of the data driver 400 are not limited thereto. That is, the data driver 400 can be composed of a plurality of integrated circuits (IC) which can be disposed on one side of the display panel 100 or multiple sides of the display panel 100.

The power supply 500 generates DC power required for driving the pixel array of the display panel 100, the gate driver 300, and the data driver 400. The power supply 500 can include a charge pump, a regulator, a buck converter, a boost converter, etc.

The power supply 500 can receive an input voltage from the host system and can generate a DC voltage such as the gate high voltage VGH, the gate low voltage VGL, the high potential driving voltage ELVDD, the low potential driving voltage ELVSS, and the reference voltage Vref. The gate low voltage VGL and the gate high voltage VGH can be supplied to the gate driver 300, and the high potential driving voltage ELVDD, the low potential driving voltage ELVSS, and the reference voltage Vref can be supplied to the pixels P.

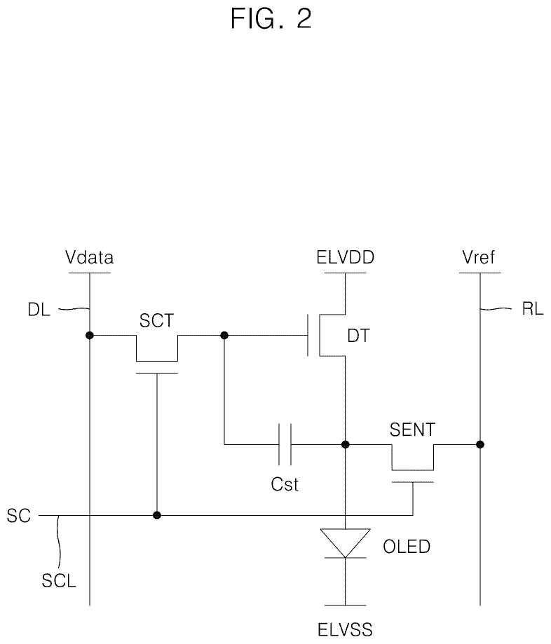

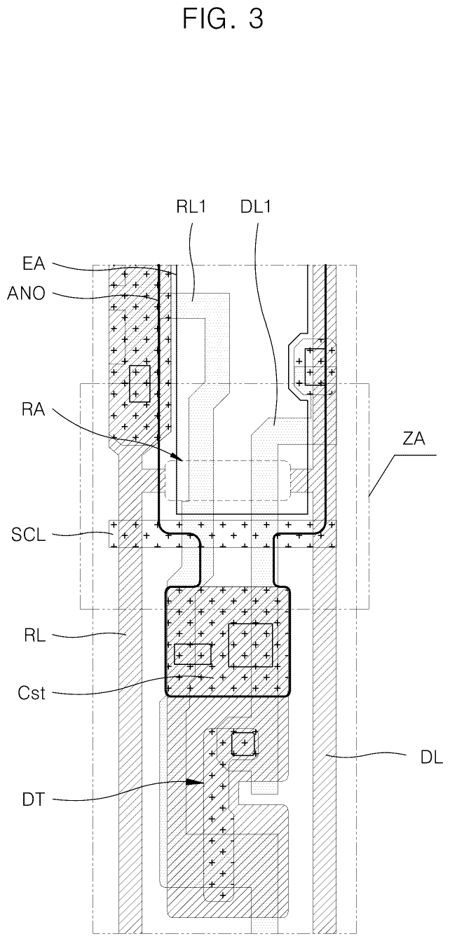

FIG. 2 is a circuit diagram of a pixel included in an organic light-emitting display device according to an embodiment of the present disclosure. FIG. 3 is a plan view of a pixel included in an organic light-emitting display device according to an embodiment of the present disclosure.

Referring to FIGS. 2 and 3, the pixel PX is defined by the scan line SCL, the data line DL, the power line, and the reference voltage line RL. A scan transistor SCT, a driving transistor DT, a light-emitting element OLED, a sensing transistor SENT, and a storage capacitor Cst are disposed in one pixel.

The scan transistor SCT functions to select a pixel to be driven by applying the data voltage Vdata to the driving transistor DT. The scan transistor SCT is disposed in an area where the scan line SCL and the data line DL intersect each other. The scan transistor SCT includes a gate electrode, a source electrode, and a drain electrode. The gate electrode is connected to the scan line SCL. The source electrode is connected to the data line DL, and the drain electrode is connected to the driving transistor DT.

The driving transistor DT functions to drive the light-emitting element OLED of the pixel selected by the scan transistor SCT. The driving transistor DT includes a gate electrode, a source electrode, and a drain electrode. The gate electrode is connected to the drain electrode SD of the scan transistor SCT, the source electrode is connected to the power line to which the high potential driving voltage ELVDD is applied, and the drain electrode is connected to an anode electrode of the light-emitting element OLED.

The storage capacitor Cst serves to sample the data voltage Vdata. The storage capacitor Cst includes one electrode and the other electrode. One electrode of the storage capacitor Cst is connected to a node between the drain electrode of the scan transistor SCT and the gate electrode of the driving transistor DT, and the other electrode of the storage capacitor Cst is connected to a node between the drain electrode of the driving transistor DT and the anode electrode of the light-emitting element OLED.

The light-emitting element OLED is configured to emit light by itself, and the intensity of light emission of light emitted therefrom is adjusted according to the amount of current flowing therein. For example, the light-emitting element OLED can be embodied as an organic light-emitting diode. The light-emitting element OLED includes the anode electrode, a light-emitting layer, and a cathode electrode. The anode electrode of the light-emitting element OLED is connected to the drain electrode of the driving transistor DT and the other electrode of the storage capacitor Cst, the cathode electrode of the light-emitting element OLED is connected to the power line to which the low-potential driving voltage ELVSS is applied, and the light-emitting layer is disposed between the anode electrode and the cathode electrode.

The sensing transistor SENT is used to initialize the anode electrode of the light-emitting element OLED and the other electrode of the storage capacitor Cst with the reference voltage Vref or to sense pixel characteristics. The sensing transistor SENT includes a gate electrode, a source electrode, and a drain electrode. A gate electrode of the sensing transistor SENT is connected to the scan line SCL, and a drain electrode of the sensing transistor SENT is connected to the anode electrode of the light-emitting element OLED, the drain electrode of the driving transistor DT, and the other electrode of the storage capacitor Cst. The source electrode of the sensing transistor SENT is connected to the reference voltage line RL. According to various embodiments, the gate electrode of the sensing transistor SENT can be connected to the sensing line that supplies a separate sensing signal.

The driving transistor DT adjusts the amount of current flowing through the light-emitting element OLED based on a magnitude of the data voltage Vdata.

In addition, according to some embodiments, at least one of the transistors of the pixel circuit can be formed as a P-type thin-film transistor or a N-type thin-film transistor. Each of the transistors including the driving transistor can be made of, for example, low-temperature polycrystalline silicon (LTPS), oxide, single-silicon, or an organic material. The light-emitting element OLED can be embodied as a self-emitting diode such as an organic light-emitting element or a micro LED. The substrate on which the pixel PX is formed can be embodied as a glass substrate, a plastic substrate, a flexible plastic substrate, a wafer, or the like.

Referring to FIG. 3, in the pixel PX, a first branch line DL1 is branched from the data line DL, and a second branch line RL1 is branched from the reference voltage line RL. The first branch line DL1 and the second branch line RL1 extend in a column direction and are arranged in a row direction. For example, first branch line DL1 and the second branch line RL1 can be spaced apart from each other along a horizontal direction, and the lengths of the first branch line DL1 and the second branch line RL1 can be parallel to each other and extend along a vertical direction that is perpendicular to the horizontal direction.

The first branch line DL1 supplies the data voltage Vdata to the sub-pixel SP, and the second branch line RL1 supplies the reference voltage Vref to the sub-pixel SP. In FIG. 3, ANO denotes an area of an anode electrode, and EA denotes a light emission area. The anode electrode ANO can be disposed to partially overlap with the data line DL, the reference voltage line RL, and the scan line SCL.

The pixel PX includes a repair area RA. The repair area RA extends across the first branch line DL1 and the second branch line RL1 in the row direction (e.g., horizontal direction), and can be defined as an area used for cutting-repairing the first branch line DL1 and the second branch line RL1.

The repair area RA can be divided into a cutting area corresponding to the first branch line DL1 and the second branch line RL1 and a groove area not corresponding to the first branch line DL1 and the second branch line RL1. The cutting area CA can be defined as an area in which the first branch line DL1 and the second branch line RL1 are cut in the repair process. The groove area A2 can be defined as an area of the repair area RA in which a groove is formed in an area that does not correspond to the first branch line DL1 and the second branch line RL1.

A repair structure including the repair area RA will be described in detail as follows.

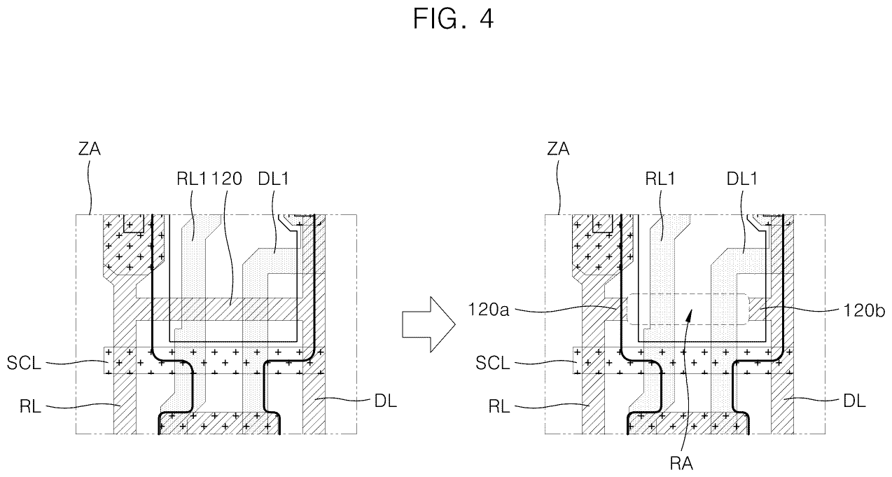

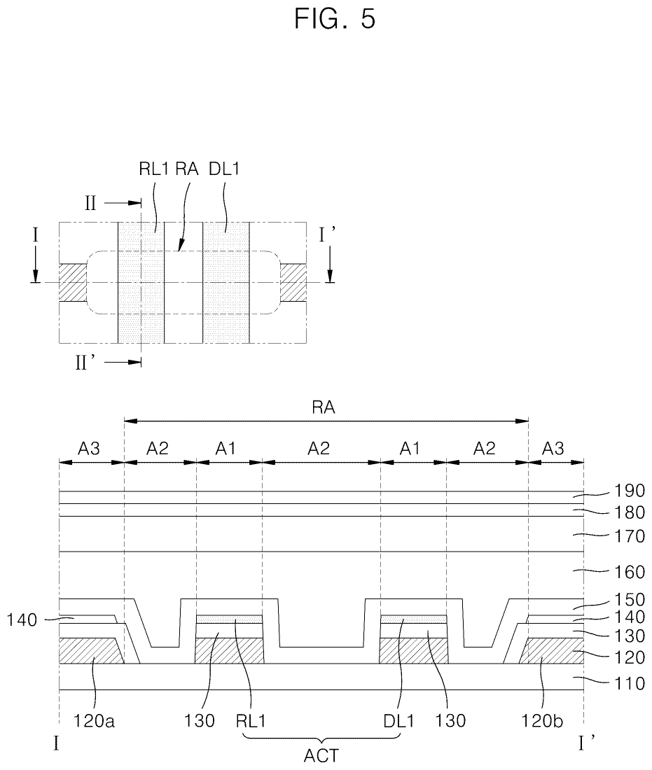

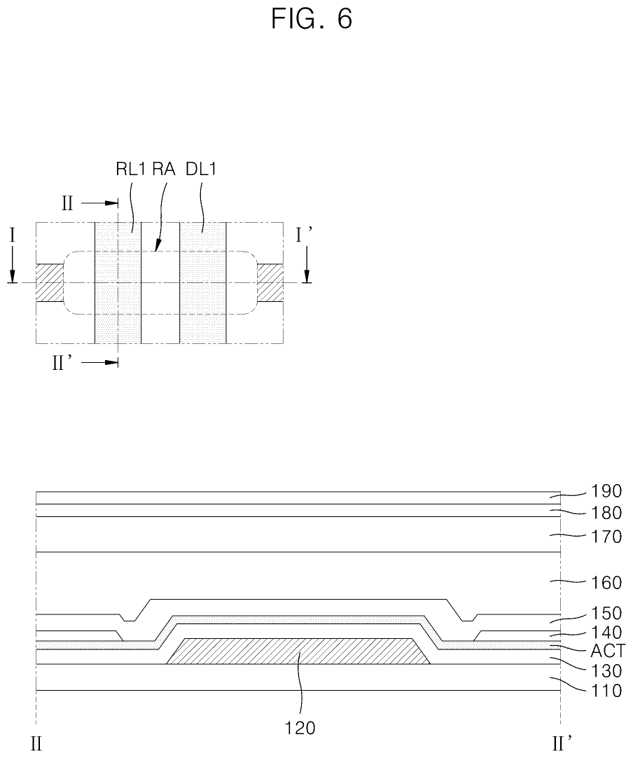

FIG. 4 is a plan view illustrating a repair structure included in an organic light-emitting display device according to an embodiment of the present disclosure. FIG. 5 is a cross-sectional view taken along a line I-I′ in a repair structure included in an organic light-emitting display device according to an embodiment of the present disclosure. FIG. 6 is a cross-sectional view taken along a line II-II′ in a repair structure included in an organic light-emitting display device according to an embodiment of the present disclosure.

Referring to FIGS. 4 to 6, the first branch line DL1 is branched from the data line DL and extends in the column direction, and the second branch line RL1 is branched from the reference voltage line RL and disposed in the column direction. The first branch line DL1 can be a first active line, and the second branch line RL1 can be a second active line.

The repair structure includes the repair area RA and a marker area A3.

The repair area RA extends across the first active line DL1 and the second active line RL1 in the row direction (e.g., horizontal direction, or direction perpendicular to the long extending direction of the first active line DL1 and the second active line RL1). When the cutting repair is performed due to a pixel defect, the first active line DL1 and the second active line RL1 are cut in the repair area RA (e.g., disconnected).

The repair area RA includes a cutting area A1 corresponding to (vertically overlapping) the first active line DL1 and the second active line RL1 and a groove area A2 not corresponding to (vertically non-overlapping) the first active line DL1 and the second active line RL1. The cutting area A1 is an area where the first active line DL1 and the second active line RL1 are cut, and the groove area A2 is an area where a groove is formed in the repair area RA.

The cutting area A1 includes a light-shielding layer 120 formed on the substrate 110, a buffer layer 130 formed on the light-shielding layer 120, and an active layer ACT formed on the buffer layer 130. Referring to the cross-sectional structure cut along a line II-II′, in the cutting area A1, a stack of the light-shielding layer 120, the buffer layer 130, and the active layer ACT has both opposing side surfaces.

The cutting area A1 further includes a protective layer 150 formed on the active layer ACT, a planarization layer 160 and 170 formed on the protective layer 150, an anode layer 180 formed on the planarization layer 160 and 170, and a cathode layer 190 formed on the anode layer 180.

The groove area A2 has a structure in which a groove is formed by removing portions of the light-shielding layer 120 and the buffer layer 130 on the substrate 110. The groove area A2 includes the protective layer 150 formed on the substrate 110, the planarization layer 160 and 170 formed on the protective layer 150, the anode layer 180 formed on the planarization layer 160 and 170, and the cathode layer 190 formed on the anode layer 180. For example, the groove area A2 in the repair area RA can include a plurality of grooves or trenches. In other words, at least one groove or trench can be formed between the first active line DL1 and the second active line RL1 that extends along the length direction (e.g., vertical direction) and additional grooves (e.g., trenches) can be formed outside of the first active line DL1 and the second active line RL1. For example, three grooves can be provided in the repair area RA, in which the first active line DL1 can be disposed between two adjacent grooves among the three grooves (e.g., on the right side of RA), and the second active line RL1 can be disposed between two adjacent grooves among the three grooves (e.g., on the left side of RA).

The marker area A3 is an area formed on each of both opposing sides in the row direction of the repair area RA, and can be defined as an area serving as a marker with respect to the repair area RA when the repair cutting is performed. For example, marker area A3 can include a horizontal extension portion jutting from the reference voltage line RL on a first side of the repair area RA, and a horizontal extension portion jutting from the data line DL on a second side of the repair area RA that is opposite to the first side of the repair area RA. Thus, the two extension portions can serve to point to or “mark” the repair area RA together with protective layer 150.

The marker area A3 includes the light-shielding layer 120 formed on the substrate 110, the buffer layer 130 formed on the light-shielding layer 120, and a gate insulating layer 140 formed on the buffer layer 130. A width in the column direction of the marker area A3 can be smaller than a width in the column direction of the repair area RA. The marker area A3 further includes the protective layer 150 formed on the gate insulating layer 140, the planarization layer 160 and 170 formed on the protective layer 150, the anode layer 180 formed on the planarization layer 160 and 170, and the cathode layer 190 formed on the anode layer 180.

Each of the first active line DL1 and the second active line RL 1 can be at least one signal line which is required to be cut when the cutting repair is performed due to a pixel defect in the display panel. For example, the first active line DL1 can be the first branch line connecting the data line DL and the sub-pixel SP to each other, and the second active line RL1 can be the second branch line connecting the reference voltage line RL and the sub-pixel SP to each other.

As described above, the repair structure included in the display panel includes the repair area RA extending across the first active line DL1 and the second active line RL1 in the row direction (e.g., direction perpendicular to the extending lengths of DL1 and RL1, or the horizontal direction). The repair area RA includes the cutting area A1 corresponding to (vertically overlapping) the first active line DL1 and the second active line RL1 and the groove area A2 not corresponding to (vertically non-overlapping) the first active line DL1 and the second active line RL1 and having the groove defined therein. The cutting repair can be performed in the high PPI pixel or the DRD pixel without causing a short-circuit between patterns during the cutting repair of a specific pixel.

In addition, the repair structure included in the display panel has a structure in which the groove area A2 of the repair area RA is formed by removing the light-shielding layer 120 and the buffer layer 130 on the substrate 110 to form the groove. Thus, the cutting repair can be performed without causing a short-circuit between patterns in a pixel having a structure in which a margin is insufficient due to a large number of lines in an opening area at a high resolution. For example, during laser cutting of conductive lines in high-resolution displays, there is a risk of creating conductive debris or melted material that may bridge gaps and cause short circuits with adjacent patterns or underlying layers. In this way, the groove(s) in groove area A2 can serve to provide effective isolation against this issue by strategically removing portions of the light-shielding and buffer layers in areas adjacent to the cut. These etched trenches or grooves can increase physical separation, eliminate potential conductive pathways these removed layers might otherwise form, and help contain cutting debris. Thus, these engineered groove(s) can prevent short circuits during repair and enable more compact display designs by negating the need for a traditional overlay margin (e.g., wiring lines can be spaced closer together and still have the option for repair cutting).

In addition, the repair structure included in the display panel further includes the marker area A3 on each of both opposing sides of the repair area RA, so that the repair area RA can be identified based on the pattern of the marker area A3 and the cutting repair can be accurately performed at a desired position by irradiating a laser onto an extension line passing through the both maker areas in the row direction.

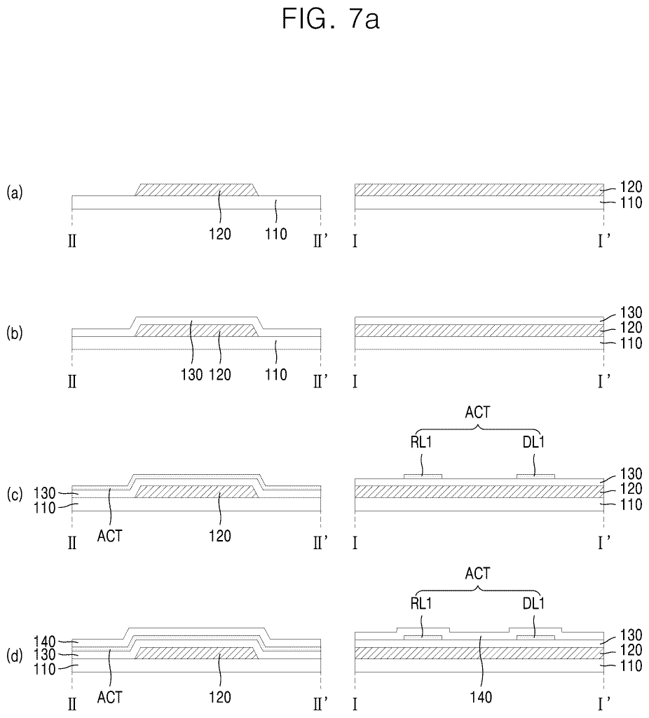

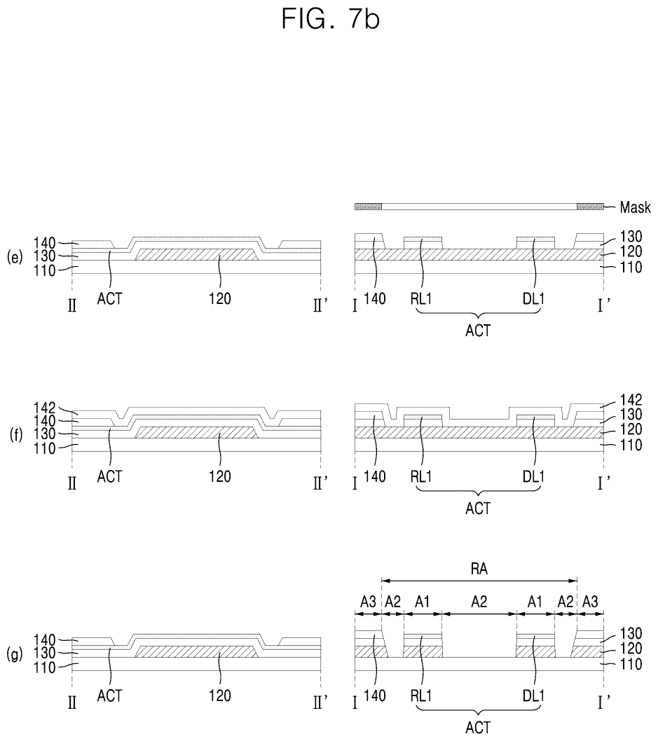

FIGS. 7a and 7b are cross-sectional views sequentially illustrating a manufacturing process of an organic light-emitting display device according to an embodiment of the present disclosure.

Referring to FIGS. 7a and 7b, the method for manufacturing the organic light-emitting display device includes a step (a) of depositing and patterning the light-shielding layer 120 on the substrate 110, and a step (b) of depositing the buffer layer 130 on the substrate 110 and the light-shielding layer 120. In particular, the step (a) of patterning the light-shielding layer 120 includes a process of patterning the light-shielding layer 120 to extend across the first active line DL1 and the second active line RL1 in the row direction.

In addition, the method for manufacturing the organic light-emitting display device further includes a step (c) of depositing the active layer ACT on the buffer layer 130 and patterning the active layer into the first active line DL1 and the second active line RL1, and a step (d) of depositing the gate insulating layer 140 on the buffer layer 130 and the first active line DL1 and the second active line RL1.

In addition, the method for manufacturing the organic light-emitting display device further includes a step (e) of defining the repair area RA extending across the first active line DL1 and the second active line RL1 in a row direction, dividing the repair area RA into the cutting area A1 and the groove area A2, etching the gate insulating layer 140 in the repair area RA, and etching the buffer layer 130 in the groove area A2. The cutting area A1 is an area in which the active layer ACT is to be cut, and the groove area A2 is an area defined in consideration of an overlay margin.

In the step (e), the gate insulating layer 140 is etched using a gate insulating layer hole mask. In this situation, the cutting area A1 is self-aligned based on the first active line DL1 and the second active line RL1. That is, the gate insulating layer 140 is removed from the cutting area A1 and the groove area A2. In this regard, the cutting area A1 can be self-aligned with the active layer ACT to be cut by a laser and have the same line width.

In addition, the method for manufacturing the organic light-emitting display device can further include a step of defining the marker area A3 on both opposing sides in the row direction of the repair area RA. In addition, the method can include a step (g) of depositing the gate layer 142 in the repair area RA and the marker area A3 and a step (f) of patterning the gate layer 142.

The step (g) of patterning the gate layer 142 can include a step of removing the gate layer 142 in the repair area RA and the marker area A3 and removing the light-shielding layer 120 in the groove area A2. That is, the repair structure is not covered with the gate layer 142 or is not covered with a metal layer in a subsequent process. As described above, the groove area A2 of the repair area RA has a structure in which the light-shielding layer and the gate layer are removed from the groove area A2 compared to a general hole patterning and a gate layer-light-shielding layer contact structure. Since the process of forming the pattern of the groove area A2 is the same as the process of forming the contact hole via which the light-shielding layer-active layer-gate layer contact each other, an additional process does not occur. For example, in step (g), a plurality of grooves or trenches can be formed in the groove area A2 which extend along the sides of the first active line DL1 and the second active line RL1 by removing portions of the gate layer 142 and the light-shielding layer 120.

In addition, the method for manufacturing the organic light-emitting display device can further include forming the protective layer 150 in the repair area RA and the marker area A3, forming the planarization layer 160 and 170 on the protective layer 150, forming the anode layer 180 on the planarization layer 160 and 170, and forming the cathode layer 190 on the anode layer 180.

When the active line ACT is made of a transparent IGZO, the light-shielding layer 120 disposed thereunder can be visible to the user to recognize the cutting area CA. In addition, even when the active line ACT is not a transparent line, the cutting area CA can be recognized due to the generation of shading due to a step formed at each of both opposing sides of the cutting area CA. The active line ACT passing over the light-shielding layer 120 has an incomplete contact area such as folds and pores. Thus, when a laser is applied thereto, a crack is generated therein at which the cutting occurs.

According to embodiments, the overlay margin in the row direction of the light-shielding layer 120 is unnecessary compared to the active line to be cut. Thus, a desired cutting repair can be performed without a short-circuit between the active lines even in a pixel structure in which the margin is insufficient due to the large number of lines in the opening area in the high PPI pixel. For example, laser cutting in high-resolution displays can create debris, leading to short circuits. The groove(s) in grove area A2 can prevent this by providing isolation. The grooves can be formed by etching away portions of the light-shielding and buffer layers near the cut, a process that can increase physical separation, eliminate potential conductive pathways, and help contain debris. Accordingly, the groove(s) in groove area A2 can prevent short circuits during repair and enable more compact display designs with closer wiring, since this design can negate the need for traditional overlay margins or larger spacing distances between wirings.

The display device and the method for manufacturing the display device according to aspects and embodiments of the present disclosure as described above can be described as follows.

A first aspect of the present disclosure provides a display device comprising: a first active line and a second active line arranged in a row direction and extending in a column direction; and a repair area extending across the first active line and the second active line in the row direction, in which the repair area includes a cutting area vertically overlapping the first active line and the second active line, and a groove area vertically non-overlapping the first active line and the second active line and having a groove defined therein.

In accordance with some embodiments of the first aspect, the cutting area includes: a light-shielding layer formed on a substrate; a buffer layer formed on the light-shielding layer; and an active layer formed on the buffer layer.

In accordance with some embodiments of the first aspect, in the groove area, the groove is formed by removing the light-shielding layer and the buffer layer on the substrate.

In accordance with some embodiments of the first aspect, the cutting area further includes a protective layer formed on the active layer, a planarization layer formed on the protective layer, an anode layer formed on the planarization layer, and a cathode layer formed on the anode layer, in which the groove area further includes the protective layer formed on the substrate, the planarization layer formed on the protective layer, the anode layer formed on the planarization layer, and the cathode layer formed on the anode layer.

In accordance with some embodiments of the first aspect, in the cutting area, a stack of the light-shielding layer, the buffer layer, and the active layer has both opposing side surfaces in the column direction.

In accordance with some embodiments of the first aspect, the display device further includes a marker area disposed on each of both opposing sides in the row direction of the repair area, in which the marker area includes a light-shielding layer formed on a substrate, a buffer layer formed on the light-shielding layer, and a gate insulating layer formed on the buffer layer.

In accordance with some embodiments of the first aspect, a width in the column direction of the marker area is smaller than a width in the column direction of the repair area.

In accordance with some embodiments of the first aspect, the marker area further includes a protective layer formed on the gate insulating layer, a planarization layer formed on the protective layer, an anode layer formed on the planarization layer, and a cathode layer formed on the anode layer.

In accordance with some embodiments of the first aspect, the first active line is a first branch line connecting a data line to a sub-pixel, in which the second active line is a second branch line connecting a reference voltage line to the sub-pixel.

A second aspect of the present disclosure provides a display device including a plurality of sub-pixels, a data line for supplying a data voltage to the plurality of sub-pixels, a reference voltage line for supplying a reference voltage to the plurality of sub-pixels, a first branch line connecting the data line to one of the plurality of sub-pixels, a second branch line connecting the reference voltage line to one of the plurality of sub-pixels, in which the second branch line and the first branch line are arranged in a row direction and extend in a column direction and in a parallel manner to each other, and a repair area extending across the first branch line and the second branch line in the row direction, in which the repair area includes a cutting area vertically overlapping the first branch line and the second branch line, and a groove area vertically non-overlapping the first branch line and the second branch line and having a groove formed therein.

In accordance with some embodiments of the second aspect, the cutting area includes a light-shielding layer formed on a substrate, a buffer layer formed on the light-shielding layer; and an active layer formed on the buffer layer.

In accordance with some embodiments of the second aspect, in the groove area, a groove is formed by removing the light-shielding layer and the buffer layer on the substrate.

In accordance with some embodiments of the second aspect, the cutting area further includes a protective layer formed on the active layer, a planarization layer formed on the protective layer, an anode layer formed on the planarization layer, and a cathode layer formed on the anode layer, in which the groove area further includes the protective layer formed on the substrate, the planarization layer formed on the protective layer, the anode layer formed on the planarization layer, and the cathode layer formed on the anode layer.

In accordance with some embodiments of the second aspect, in the cutting area, a stack of the light-shielding layer, the buffer layer, and the active layer has both opposing side surfaces in the column direction.

In accordance with some embodiments of the second aspect, the display device further includes a marker area disposed on each of both opposing sides in the row direction of the repair area, in which the marker area includes a light-shielding layer formed on a substrate, a buffer layer formed on the light-shielding layer, and a gate insulating layer formed on the buffer layer.

In accordance with some embodiments of the second aspect, a width in the column direction of the marker area is smaller than a width in the column direction of the repair area.

In accordance with some embodiments of the second aspect, the marker area further includes a protective layer formed on the gate insulating layer, a planarization layer formed on the protective layer, an anode layer formed on the planarization layer, and a cathode layer formed on the anode layer.

A third aspect of the present disclosure provides a method for manufacturing a display device, the method including depositing and patterning a light-shielding layer on a substrate, depositing a buffer layer on the substrate and the light-shielding layer, depositing an active layer on the buffer layer and patterning the active layer into a first active line and a second active line, depositing a gate insulating layer on the buffer layer, the first active line, and the second active line, and defining a repair area to extend the first active line and the second active line in a row direction, dividing the repair area into a cutting area and a groove area, and etching the gate insulating layer in the repair area and etching the buffer layer in the groove area.

In accordance with some embodiments of the third aspect, the method further includes defining a marker area on each of both opposing sides in the row direction of the repair area, depositing a gate layer in the repair area and the marker area; and patterning the gate layer, in which the patterning of the gate layer includes removing the gate layer in the repair area and the marker area, and removing the light-shielding layer in the groove area.

In accordance with some embodiments of the third aspect, the method further includes forming a protective layer in the repair area and the marker area, forming a planarization layer on the protective layer, forming an anode layer on the planarization layer, and forming a cathode layer on the anode layer.

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display device comprising:
a first active line and a second active line arranged in a row direction and extending in a column direction; and
a repair area extending across the first active line and the second active line in the row direction,
wherein the repair area includes:
a cutting area vertically overlapping with the first active line and the second active line; and
a groove area vertically non-overlapping with the first active line and the second active line, the groove area including at least one groove.

2. The display device of claim 1, wherein the cutting area includes:
a light-shielding layer disposed on a substrate;
a buffer layer disposed on the light-shielding layer; and
an active layer disposed on the buffer layer.

3. The display device of claim 2, wherein the at least one groove is based on a hole or a depression in the light-shielding layer and the buffer layer.

4. The display device of claim 3, wherein the cutting area further includes:
a protective layer disposed on the active layer;
a planarization layer disposed on the protective layer;
an anode layer disposed on the planarization layer; and
a cathode layer disposed on the anode layer, and
wherein the groove area further includes:
a portion of the protective layer disposed on the substrate,
a portion of the planarization layer disposed on the protective layer,
a portion of the anode layer disposed on the planarization layer, and
a portion of the cathode layer disposed on the anode layer.

5. The display device of claim 2, wherein a stack of the light-shielding layer, the buffer layer, and the active layer is in the cutting area, and
wherein the stack has both opposing side surfaces in the column direction.

6. The display device of claim 1, wherein the display device further includes a marker area disposed on opposing sides of the repair area, and
wherein the marker area includes a light-shielding layer disposed on a substrate, a buffer layer disposed on the light-shielding layer, and a gate insulating layer disposed on the buffer layer.

7. The display device of claim 6, wherein a width of the marker area in the column direction is smaller than a width of the repair area in the column direction.

8. The display device of claim 6, wherein the marker area further includes:
a protective layer disposed on the gate insulating layer;
a planarization layer disposed on the protective layer;
an anode layer disposed on the planarization layer; and
a cathode layer disposed on the anode layer.

9. The display device of claim 1, wherein the first active line is a first branch line connecting a data line to a sub-pixel, and
wherein the second active line is a second branch line connecting a reference voltage line to the sub-pixel.

10. A display device comprising:
a plurality of sub-pixels;
a data line configured to supply a data voltage to the plurality of sub-pixels;
a reference voltage line configured to supply a reference voltage to the plurality of sub-pixels;
a first branch line connecting the data line to one of the plurality of sub-pixels;
a second branch line connecting the reference voltage line to the one of the plurality of sub-pixels, the second branch line and the first branch line being arranged in a row direction and extending in a column direction and in parallel to each other; and
a repair area extending across the first branch line and the second branch line in the row direction,
wherein the repair area includes:
a cutting area vertically overlapping with the first branch line and the second branch line; and
a groove area vertically non-overlapping with the first branch line and the second branch line, the groove area including at least one groove.

11. The display device of claim 10, wherein the cutting area includes:
a light-shielding layer disposed on a substrate;
a buffer layer disposed on the light-shielding layer; and
an active layer disposed on the buffer layer.

12. The display device of claim 11, wherein the at least one groove includes a hole or a depression in the light-shielding layer and the buffer layer.

13. The display device of claim 12, wherein the cutting area further includes:
a protective layer disposed on the active layer; a planarization layer formed on the protective layer;
an anode layer disposed on the planarization layer; and
a cathode layer disposed on the anode layer, and
wherein the groove area further includes:
a portion of the protective layer disposed on the substrate,
a portion of the planarization layer disposed on the protective layer,
a portion of the anode layer disposed on the planarization layer, and
a portion of the cathode layer disposed on the anode layer.

14. The display device of claim 11, wherein in the cutting area includes a stack of the light-shielding layer, the buffer layer, and
wherein opposing side surfaces of the active layer are arranged in the column direction.

15. The display device of claim 10, wherein the display device further includes a marker area disposed on opposing sides of the repair area, and
wherein the marker area includes a light-shielding layer disposed on a substrate, a buffer layer disposed on the light-shielding layer, and a gate insulating layer disposed on the buffer layer.

16. The display device of claim 15, wherein a width of the marker area in the column direction is smaller than a width of the repair area in the column direction.

17. The display device of claim 16, wherein the marker area further includes:
a protective layer disposed on the gate insulating layer;
a planarization layer disposed on the protective layer;
an anode layer disposed on the planarization layer; and
a cathode layer disposed on the anode layer.

18. A method for manufacturing a display device, the method comprising:
depositing and patterning a light-shielding layer on a substrate;
depositing a buffer layer on the substrate and the light-shielding layer;
depositing an active layer on the buffer layer and patterning the active layer into a first active line and a second active line;
depositing a gate insulating layer on the buffer layer, the first active line, and the second active line; and
defining a repair area to extend across the first active line and the second active line in a row direction, dividing the repair area into a cutting area and a groove area, and etching the gate insulating layer in the repair area and etching the buffer layer in the groove area.

19. The method for manufacturing the display device of claim 18, wherein the method further comprises:
defining a marker area on opposing sides of the repair area in the row direction;
depositing a gate layer in the repair area and the marker area; and
patterning the gate layer,
wherein the patterning of the gate layer includes removing portions of the gate layer in the repair area and the marker area, and removing a portion of the light-shielding layer in the groove area.

20. The method for manufacturing the display device of claim 19, wherein the method further comprises:
forming a protective layer in the repair area and the marker area;
forming a planarization layer on the protective layer;
forming an anode layer on the planarization layer; and
forming a cathode layer on the anode layer.

21. A display device comprising:
a plurality of sub-pixels;
a data line configured to supply a data voltage to the plurality of sub-pixels;
a reference voltage line configured to supply a reference voltage to the plurality of sub-pixels;
a first branch line connecting the data line to one of the plurality of sub-pixels;
a second branch line connecting the reference voltage line to the one of the plurality of sub-pixels, the second branch line extending parallel to the first branch line; and
a repair area extending across the first branch line and the second branch line,
wherein the repair area includes:
a first groove between the first branch line and the second branch line, and
a second groove and a third groove, the first branch line and the second branch line being located between the second groove and the third groove.

22. The display device of claim 21, wherein the repair area further includes:
a light-shielding layer disposed on a substrate;
a buffer layer disposed on the light-shielding layer,
wherein the first groove includes a first hole that extends through both of the light-shielding layer and the buffer layer,
wherein the second groove includes a second hole that extends through both of the light-shielding layer and the buffer layer, and
wherein the third groove includes a third hole that extends through both of the light-shielding layer and the buffer layer.

23. The display device of claim 21, wherein the repair area further includes:
a maker area including a first extension portion protruding from the reference voltage line on a first side of the repair area, and a second extension portion protruding from the data line on a second side of the repair area.

24. The display device of claim 21, wherein first, second and third grooves are configured to trap or contain conductive debris generated during a cutting repair process that cuts through the first branch line and the second branch line.
